(19) United States
(12) Patent Application Publication
(10) Pub. No.: US 2026/0214945 A1
(43) Pub. Date: Jul. 23, 2026

(54) THIN FILM TRANSISTOR AND MANUFACTURING METHOD THEREOF, ARRAY SUBSTRATE AND DISPLAY PANEL

(71) Applicants: Yungu (Gu’an) Technology Co., Ltd., Langfang (CN); Hefei Visionox Technology Co., Ltd., Hefei (CN)

(72) Inventors: Guowen YAN, Langfang (CN); Xiaoqi SUN, Langfang (CN); Lin XU, Langfang (CN); Dejian WANG, Langfang (CN); Lidong DING, Langfang (CN); Fa-Hsyang CHEN, Langfang (CN)

(73) Assignees: Yungu (Gu’an) Technology Co., Ltd., Langfang (CN); Hefei Visionox Technology Co., Ltd., Hefei (CN)

(21) Appl. No.: 19/567,232

(22) Filed: Mar. 15, 2026

Related U.S. Application Data
(63) Continuation of application No. PCT/CN2024/095701, filed on May 28, 2024.

(30) Foreign Application Priority Data
Sep. 27, 2023 (CN) 202311269711.4

(51) Int. Cl. H10D 30/67; H10D 30/01

(52) U.S. Cl. CPC H10D 30/6755; H10D 30/031; H10D 30/6723

(57) ABSTRACT

The present application discloses a thin film transistor, a preparation method thereof, an array substrate and a display panel. The thin film transistor provided in the present application includes an active layer, the active layer includes a plurality of sub-active layers, the plurality of sub-active layers are stacked along a first direction, each sub-active layer includes a crystalline oxide material, and atomic percentage of indium element in adjacent sub-active layers is different.

### CROSS-REFERENCE TO RELATED APPLICATIONS

The present application is a continuation of International Application No. PCT/CN 2024/095701 filed on May 28, 2024, which claims priority to Chinese Patent Application No. 202311269711.4, filed on Sep. 27, 2023. All of the aforementioned patent applications are hereby incorporated by reference in their entireties.

### FIELD

The present application belongs to the field of display technology, and particularly relates to a thin film transistor and a manufacturing method thereof, an array substrate and a display panel.

### BACKGROUND

With the development of display technology, the performance requirements for display devices are increasing. A display device includes a light-emitting layer and a driving circuit. The driving circuit is used to drive the light-emitting layer to emit light. The driving circuit includes thin film transistors. The greater the mobility and the better the conductivity of a thin film transistor, the stronger its light stability and the more stable its device performance. However, thin film transistors in related technologies cannot achieve a balance between mobility and light illumination stability, making it difficult for their overall performance to meet requirements.

### SUMMARY

Embodiments of the present application provide a thin film transistor and a manufacturing method thereof, an array substrate and a display panel, which can achieve a balance between mobility and light illumination stability, thereby improving the overall performance of the thin film transistor.

An embodiment according to an embodiment of the present application provides a thin film transistor, including an active layer. The active layer includes a plurality of sub-active layers. The plurality of sub-active layers are stacked along a first direction. The sub-active layers include a crystalline oxide material, and the atomic percentage of indium element in adjacent sub-active layers is different.

An embodiment according to an embodiment of the present application provides a method for manufacturing a thin film transistor, including:
sequentially depositing crystalline oxide materials having different atomic percentages of indium element to sequentially form a plurality of sub-active layers stacked along a first direction, and the atomic percentage of indium element in adjacent sub-active layers is different, thereby forming an active layer.

An embodiment according to an embodiment of the present application further provides an array substrate, including the thin film transistor provided in the first aspect of the present application.

An embodiment according to an embodiment of the present application further provides a display panel, including the array substrate provided in the third aspect of the present application.

In the thin film transistor provided by the present application, an active layer is included. The active layer includes a plurality of sub-active layers. The plurality of sub-active layers are stacked along a first direction. The sub-active layers include a crystalline oxide material, and the atomic percentage of indium element in adjacent sub-active layers is different. On one hand, using the crystalline oxide material as the material for the active layer can enable the thin film transistor to have high mobility and good light illumination stability. Moreover, the better the crystallinity of the oxide material, the better the mobility and light illumination stability of the thin film transistor, thereby achieving a balance between the mobility and light illumination stability of the thin film transistor. On the other hand, the better the crystallinity of the oxide material, the more difficult it is to etch. A sub-active layer with a lower atomic percentage of indium element is easily wet-etched but has poorer crystallinity, and its mobility is lower than that of a sub-active layer with a higher atomic percentage of indium element. A sub-active layer with a higher atomic percentage of indium element has better crystallinity and higher mobility but is not easily wet-etched. Therefore, in the present application, by arranging a plurality of sub-active layers and making the atomic percentage of indium element different in adjacent sub-active layers, etching difficulty and crystallinity can be balanced, thereby facilitating the reduction of the patterning difficulty of the active layer during the manufacturing process.

### BRIEF DESCRIPTION OF THE DRAWINGS

FIG. 1 is a top view of a thin film transistor provided by an embodiment of the present application;

FIG. 2 is a cross-sectional view taken along line P-P′ in FIG. 1;

FIG. 3 is a schematic structural diagram of an active layer in a thin film transistor provided by an embodiment of the present application;

FIG. 4 is a schematic structural diagram of another thin film transistor provided by an embodiment of the present application;

FIG. 5 is a schematic structural diagram of an active layer in another thin film transistor provided by an embodiment of the present application;

FIG. 6 is a schematic structural diagram of an active layer in another thin film transistor provided by an embodiment of the present application;

FIG. 7 is a schematic structural diagram of an active layer in another thin film transistor provided by an embodiment of the present application;

FIG. 8 is a schematic structural diagram of an active layer in another thin film transistor provided by an embodiment of the present application;

FIG. 9 is a flowchart of a method for manufacturing a thin film transistor provided by an embodiment of the present application;

FIG. 10 is a schematic structural diagram of an array substrate provided by an embodiment of the present application;

FIG. 11 is a schematic structural diagram of a display panel provided by an embodiment of the present application.

### DETAILED DESCRIPTION OF THE EMBODIMENTS

Through research, the inventors have found that the active layer of thin film transistors in related technologies is mainly composed of indium, gallium, zinc, and doping elements. Among these, the mobility of an indium gallium zinc oxide active layer can be adjusted by adjusting the content of indium, gallium, and zinc. However, in indium gallium zinc oxide, mobility and the light illumination stability (NBTIS) of the thin film transistor are conflicting. Low mobility results in good light illumination stability but poor conductivity; high mobility results in poor light illumination stability, causing the channel region of the thin film transistor to be easily affected by light illumination, thereby affecting its own performance. Therefore, thin film transistors in related technologies have difficulty achieving a balance between mobility and light illumination stability, resulting in poor overall performance of the thin film transistors. Based on research into the above problems, the inventors provide a thin film transistor and a manufacturing method thereof, an array substrate and a display panel, to achieve a balance between mobility and light illumination stability, thereby improving the overall performance of the thin film transistor.

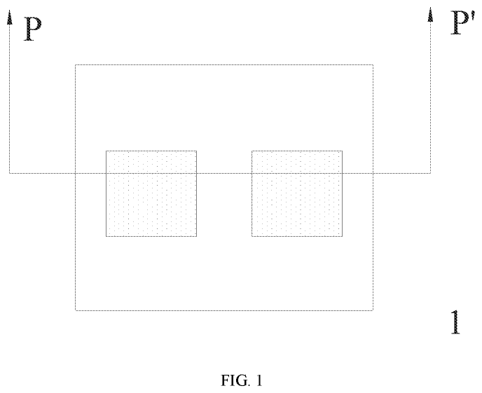

To better understand the present application, the thin film transistor and its manufacturing method, array substrate and display panel according to embodiments of the present application will be described in detail below with reference to FIG. 1 to FIG. 11.

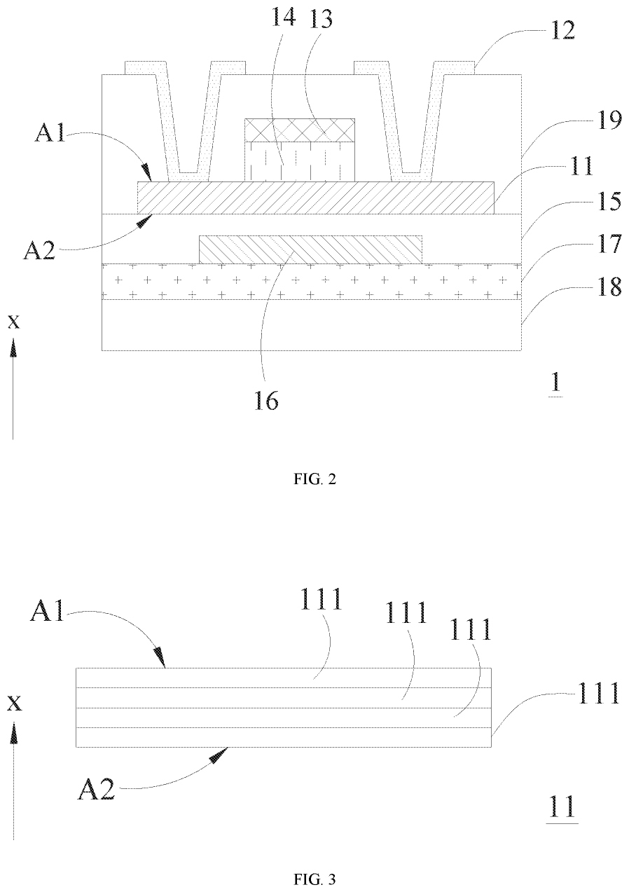

Please refer to FIG. 1, FIG. 2, and FIG. 3. An embodiment of the present application provides a thin film transistor 1, including an active layer 11. The active layer 11 includes a plurality of sub-active layers 111. The plurality of sub-active layers 111 are stacked along a first direction x. The sub-active layers 111 include a crystalline oxide material, and the atomic percentage of indium element in adjacent sub-active layers 111 is different.

In the thin film transistor 1 provided in this application, an active layer 11 is included. The active layer 11 includes multiple sub-active layers 111. The multiple sub-active layers 111 are stacked along a first direction x. The sub-active layers 111 include a crystalline oxide material, and the atomic proportion of indium elements in adjacent sub-active layers 111 is different. In one aspect, using the crystalline oxide material as the material for the active layer 11 can enable the thin film transistor 1 to have high mobility and good light stability. Moreover, the better the crystallinity of the oxide material, the better the mobility and light stability of the thin film transistor 1, thereby achieving a balance between mobility and light stability in the thin film transistor 1. On the other hand, the better the crystallinity of the oxide material, the more difficult it is to etch. Sub-active layers 111 with a lower atomic proportion of indium elements are easily wet-etched but have poorer crystallinity and lower mobility compared to sub-active layers 111 with a higher atomic proportion of indium elements. Sub-active layers 111 with a higher atomic proportion of indium elements have better crystallinity and higher mobility but are not easily wet-etched. Therefore, in this application, by arranging multiple sub-active layers 111 and ensuring that the atomic proportion of indium elements in adjacent sub-active layers 111 is different, the etching difficulty and crystallinity can be balanced, thereby reducing the patterning difficulty of the active layer 11 during the preparation process.

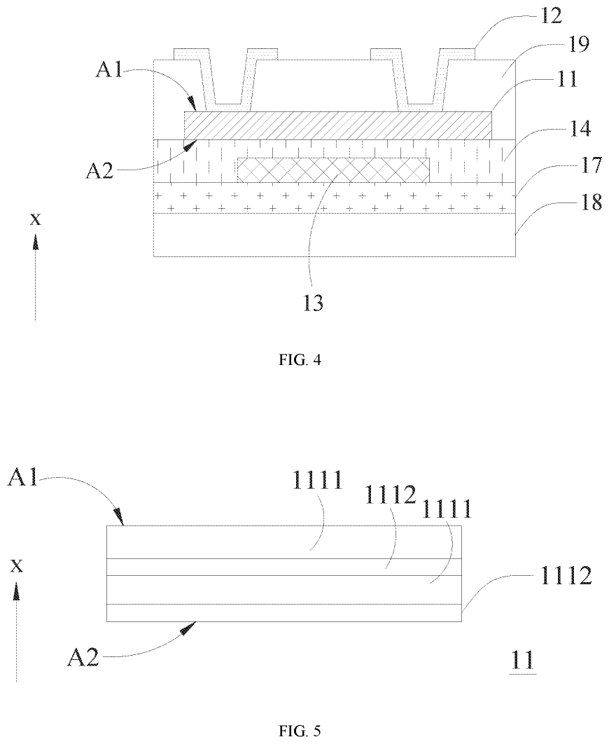

As shown in FIG. 2 and FIG. 4, the thin film transistor 1 provided in this application further includes a source-drain electrode layer 12 and a gate electrode 13. The active layer 11 includes a first side A1 and a second side A2, arranged along the first direction x. The source-drain electrode layer 12 is formed on the first side A1 and is connected to the active layer 11. The gate electrode 13 is formed on the first side A1 or the second side A2 and is insulated from both the active layer 11 and the source-drain electrode layer 12. In one embodiment, the thin film transistor 1 can have a top-gate structure or a bottom-gate structure. When the gate electrode 13 is located on the first side A1, it is a top-gate structure; when the gate electrode 13 is located on the second side A2, it is a bottom-gate structure. This application does not impose any special limitations on this.

In some embodiments, as shown in FIG. 2, the thin film transistor 1 has a top-gate structure. The gate electrode 13 is formed on the first side A1 and is insulated from the active layer 11 by a first insulating layer 14. It also includes a second insulating layer 15, a light-shielding layer 16, a buffer layer 17, and a substrate 18, which are sequentially stacked on the second side A2 in a direction away from the active layer 11. The projection of the light-shielding layer 16 in the first direction x covers the projection of the gate electrode 13 in the first direction x.

Here, the light-shielding layer 16 can be used to shield the channel region in the active layer 11, reducing the impact of light on the channel region and thereby improving the stability of the thin film transistor 1.

In some embodiments, as shown in FIG. 4, the thin film transistor 1 has a bottom-gate structure. The gate electrode 13 is formed on the second side A2 and is insulated from the active layer 11 by the first insulating layer 14.

In some embodiments, the thin film transistor 1 may further include an interlayer dielectric layer 19. The source-drain electrode layer 12 includes source and drain electrodes, which are connected to the active layer 11 through vias penetrating the interlayer dielectric layer 19.

In some embodiments, the thin film transistor 1 may also have a dual-gate structure (not shown in the FIGs). In this case, the gate electrode 13 is simultaneously formed on both the first side A1 and the second side A2. The gate electrode 13 formed on the first side A1 and the gate electrode formed on the second side A2 are both insulated from the active layer 11 by the first insulating layer 14.

In some embodiments, the crystalline oxide material includes indium gallium oxide, and the ratio of the total number of atoms in the indium gallium oxide to the total number of atoms in the crystalline oxide material is in a range of 70% to 100%.

In the above implementation, the crystalline oxide material mainly includes indium gallium oxide. Indium gallium oxide can form a crystalline state, and the higher the indium content, the better the crystallinity in subsequent processes, and the higher the mobility of the thin film transistor 1. In contrast, indium gallium zinc oxide (IGZO), which is commonly used as the material for the active layer 11 in some prior art, typically does not form a crystalline state under standard processing conditions.

Here, the material of the sub-active layers 111 may include only the crystalline oxide material to enhance its balance between mobility and light stability.

Here, the indium gallium oxide material includes indium gallium oxide, and the ratio of the total number of atoms in the indium gallium oxide to the total number of atoms in the crystalline oxide material is in a range of 70% to 100%. Specific values may include 70%, 72%, 79%, 80%, 85%, 90%, 92%, 94%, 97%, 100%, etc. This application does not impose any special limitations on this. The higher the ratio of the total number of atoms in the indium gallium oxide to the total number of atoms in the crystalline oxide material, the better the mobility and light stability of the thin film transistor.

In some embodiments, as shown in FIG. 5, the multiple sub-active layers 111 include at least one first sub-active layer 1111 and at least one second sub-active layer 1112. The atomic proportion of indium elements in the first sub-active layer 1111 is less than that in the second sub-active layer 1112, and the atomic proportion of gallium elements in the first sub-active layer 1111 is greater than that in the second sub-active layer 1112.

In the above implementation, the multiple sub-active layers 111 may include sub-active layers 111 with two different atomic proportions, namely the first sub-active layer 1111 and the second sub-active layer 1112. In one embodiment, the multiple sub-active layers 111 may include sub-active layers 111 with multiple atomic proportions, such as three types of sub-active layers 111 or more. This application does not impose any special limitations on this.

In some embodiments, the atomic percentage of indium in the first sub-active layer 1111 is less than that in the second sub-active layer 1112, and the atomic percentage of gallium in the first sub-active layer 1111 is greater than that in the second sub-active layer 1112. Since a higher atomic percentage of indium leads to better crystallinity in subsequent processes and higher mobility of the thin-film transistor 1, but better crystallinity of indium gallium oxide results in better crystallization effects, making wet etching more difficult. Therefore, the crystallinity of the first sub-active layer 1111 is weaker than that of the second sub-active layer 1112, but its etching difficulty is lower than that of the second sub-active layer 1112. The crystallinity of the second sub-active layer 1112 is stronger than that of the first sub-active layer 1111, resulting in better mobility and light stability, but its etching difficulty is higher than that of the first sub-active layer 1111. Thus, by configuring the active layer 11 to include the stacked first sub-active layer 1111 and second sub-active layer 1112, the etching difficulty of the active layer 11 can be reduced via the first sub-active layer 1111 to improve fabrication feasibility, while the mobility and light stability can be enhanced via the second sub-active layer 1112, thereby achieving comprehensive improvement in the performance of the thin-film transistor 1 itself.

In some embodiments, as shown in FIG. 5, the first sub-active layer 1111 and the second sub-active layer 1112 are alternately arranged along the first direction x. The active layer 11 includes a first side A1 and a second side A2, which are arranged along the first direction x. One of the first sub-active layers 1111 is close to the first side A1, and one of the second sub-active layers 1112 is close to the second side A2.

In the above embodiment, by configuring one of the second sub-active layers 1112 to be close to the second side A2, this second sub-active layer 1112 can be fabricated first during the preparation of the active layer 11. Since the atomic percentage of indium in the second sub-active layer 1112 is greater than that in the first sub-active layer 1111, this higher indium percentage can provide high mobility and high crystallization quality for the thin-film transistor 1. During the fabrication process, when the first sub-active layer 1111 is formed above this second sub-active layer 1112, the second sub-active layer 1112 induces crystallization of the first sub-active layer 1111 in contact with it. This improves the crystallinity and mobility of the upper first sub-active layer 1111, while maintaining the low etching difficulty characteristic of the first sub-active layer 1111, thereby reducing the patterning difficulty of the active layer 11. Meanwhile, the first sub-active layer 1111 can supply oxygen atoms to the second sub-active layer 1112, regulating the carrier concentration of the second sub-active layer 1112. Under the induction of the second sub-active layer 1112 during film formation the first sub-active layer 1111 can achieve better crystallinity and mobility.

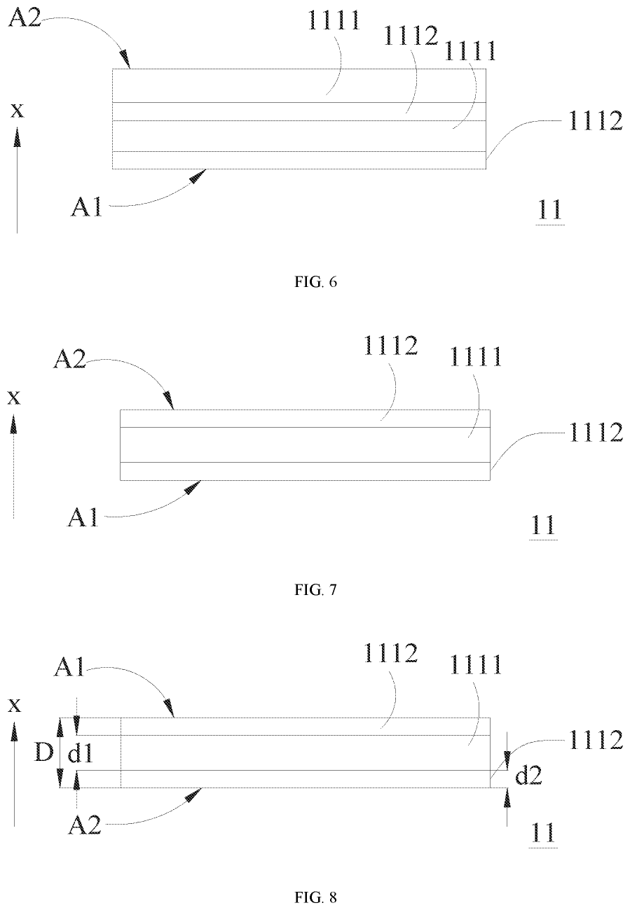

In some embodiments, in the above embodiment, the number of sub-active layers 111 may be odd or even. As shown in FIG. 6, when the number of sub-active layers 111 is even, and when one of the second sub-active layers 1112 is close to the first side A1, one of the first sub-active layers 1111 is close to the second side A2. As shown in FIG. 5, when one of the second sub-active layers 1112 is close to the second side A2, one of the first sub-active layers 1111 is close to the first side A1. As shown in FIG. 7, when the number of sub-active layers 111 is odd, and when one of the second sub-active layers 1112 is close to the first side A1, another second sub-active layer 1112 is close to the second side A2. As shown in FIG. 8, when one of the second sub-active layers 1112 is close to the second side A2, another second sub-active layer 1112 is close to the first side A1.

In some embodiments, in the first sub-active layer 1111, the atomic number of indium is a, the atomic number of gallium is b, α=a/(a+b), β=b/(a+b), where 50%≤α≤80%, 20%≤β≤50%.

In one embodiment, α may be 50%, 55%, 57%, 63%, 68%, 70%, 72%, 79%, 80%, etc., and β may be 20%, 21%, 24%, 28%, 35%, 46%, 50%, etc. This application does not impose special limitations on these values, and they can be selected according to actual requirements.

In one embodiment, within the above numerical ranges, α can be set to a smaller value and β to a larger value in the first sub-active layer 1111 to further reduce the etching difficulty of the active layer 11.

In some embodiments, in the second sub-active layer 1112, the atomic number of indium is c, the atomic number of gallium is d, γ=c/(c+d), δ=d/(c+d), where 80%≤γ≤100%, 0≤δ≤20%.

In one embodiment, in the second sub-active layer 1112, γ may be 80%, 83%, 88%, 90%, 95%, 96%, 99%, 100%, etc., and δ may be 5%, 8%, 10%, 11%, 15%, 18%, 20%, etc. This application does not impose special limitations on these values, and they can be selected according to actual requirements.

In one embodiment, within the above numerical ranges, a larger γ and a smaller δ can be selected for the second sub-active layer 1112 to further enhance the mobility of the active layer 11.

In some embodiments, as shown in FIG. 8, the dimension D of the active layer 11 along the first direction x is in a range of 3 nm to 50 nm.

In the above embodiment, the dimension of the active layer 11 along the first direction x may in one embodiment be 3 nm, 5 nm, 10 nm, 13 nm, 17 nm, 20 nm, 26 nm, 28 nm, 30 nm, 35 nm, 40 nm, 43 nm, 48 nm, 50 nm, etc. This application does not impose special limitations on these values.

When the dimension of the active layer 11 along the first direction x is too small, it may easily increase the risk of fracture and is not conducive to ensuring the yield of the thin-film transistor 1. When the dimension of the active layer 11 along the first direction x is too large, the fabrication cost is higher and etching becomes more difficult. Therefore, setting the dimension of the active layer 11 along the first direction x within the above range can simultaneously balance the yield and manufacturing cost of the active layer 11.

In some embodiments, as shown in FIG. 8, the dimension of the first sub-active layer 1111 along the first direction x is in a range of 1 nm to 10 nm.

In one embodiment, the dimension of the first sub-active layer 1111 along the first direction x may be 1 nm, 2 nm, 3 nm, 5 nm, 6 nm, 7 nm, 10 nm, etc., which is not particularly limited in this application.

In some embodiments, as shown in FIG. 8, the dimension of the second sub-active layer 1112 along the first direction x is in a range of 0.5 nm to 5 nm.

In one embodiment, the dimension of the second sub-active layer 1112 along the first direction x may be 0.5 nm, 1 nm, 1.5 nm, 2 nm, 3 nm, 3.5 nm, 4.5 nm, 5 nm, etc., which is not particularly limited in this application.

In some embodiments, the dimension of the first sub-active layer 1111 along the first direction x may be set to be greater than the dimension of the second sub-active layer 1112 along the first direction x. The first sub-active layer 1111 primarily influences in the etching difficulty of the active layer 11. The thicker the first sub-active layer 1111 and the greater its thickness proportion in the active layer 11, the lower the etching difficulty of the active layer 11. The second sub-active layer 1112 primarily influences in the mobility and illumination reliability of the active layer 11. The thicker the second sub-active layer 1112 and the greater its thickness proportion in the active layer 11, the better the mobility and illumination reliability of the active layer 11. That is, the above setting method can ensure that both the etching difficulty and the mobility and illumination reliability of the active layer 11 meet the requirements.

In one embodiment, the thickness of each sub-active layer 111 can be adjusted according to the etching selectivity difference (the ratio of etching rates between different materials) and the mobility requirements of the thin-film transistor 1.

In some embodiments, in the active layer 11, the atomic proportion of indium element in the first sub-active layer 111 close to the first side A1 or the second sub-active layer 111 close to the second side A2 is greater than or equal to the atomic proportion of indium element in any other sub-active layer 111.

In the above embodiment, by making the atomic proportion of indium element in the first sub-active layer 111 close to the first side A1 or the second sub-active layer 111 close to the second side A2 greater than or equal to that in any other sub-active layer 111, during the preparation process, the sub-active layer 111 with the highest atomic proportion of indium element among all sub-active layers 111 can be prepared first, and then other sub-active layers 111 can be prepared on this sub-active layer 111. Since the atomic proportions of indium element in two adjacent sub-active layers 111 are different, the atomic proportion of indium element in the sub-active layer 111 located above and adjacent to this sub-active layer 111 is relatively small. This sub-active layer 111 can induce crystallization of the upper sub-active layers 111, thereby improving the crystallinity and mobility of the upper sub-active layers 111, while maintaining the easy-to-etch characteristic brought by the lower atomic proportion of indium element in the upper sub-active layers 111.

In some embodiments, the active layer 11 further includes doping particles, and the ratio of the total atomic number of the doping particles to the total atomic number in the crystalline oxide material is greater than 0% and less than or equal to 30%.

In one embodiment, the doping particles include at least one of tin and germanium.

In the above embodiment, the active layer 11 includes a crystalline oxide material and doping particles. The doping particles can enhance the diversity of the active layer 11. Easily obtainable doping particles can be selected according to actual preparation conditions. Lower-cost crystalline particles can be chosen while ensuring crystallinity, thereby reducing the preparation cost of the active layer 11. In one embodiment, the doping particles include at least one of tin and germanium, and the ratio of the total atomic number of the doping particles to the total atomic number in the crystalline oxide material is greater than 0 and less than or equal to 30%, thereby ensuring that the main material of the active layer 11 is indium gallium oxide, thus achieving a balance between mobility and illumination stability.

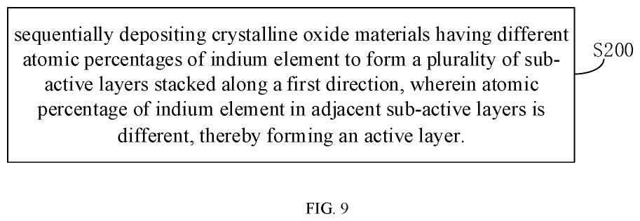

This application also provides a method for preparing a thin-film transistor 1, as shown in FIG. 9, including:
S200, sequentially depositing crystalline oxide materials with different atomic proportions of indium element to form multiple sub-active layers 111 stacked along the first direction x in sequence, and the atomic proportions of indium element in adjacent sub-active layers 111 are different, thereby forming the active layer 11.

In one embodiment, the crystalline oxide material is deposited using an atomic layer deposition process.

In the method for preparing the thin-film transistor 1 provided in this application, the sub-active layers 111 are prepared by an atomic layer deposition process, which facilitates controlling the atomic proportion of the deposited film according to the requirements of the atomic proportion, thereby accurately preparing sub-active layers 111 with a preset atomic proportion. The preparation method is simple and has high accuracy.

In one embodiment, the active layer 11 includes a first side A1 and a second side A2, which are arranged along the first direction x. The preparation method further includes:
S400, forming a gate electrode 13 on the first side A1 or the second side A2, and the gate electrode 13 is insulated from the active layer 11.
S600, forming a source-drain electrode layer 12 on the first side A1, and the source-drain electrode layer 12 is connected to the active layer 11 and insulated from the gate electrode 13.

Before the above step S200, S100 can also be included: providing a substrate 18, and sequentially forming a buffer layer 17, a light-shielding layer 16, and a second insulating layer 15 on the substrate 18; or, providing a substrate 18, and sequentially forming a buffer layer 17, a gate electrode 13, and a first insulating layer 14 on the substrate 18. This is not particularly limited in this application.

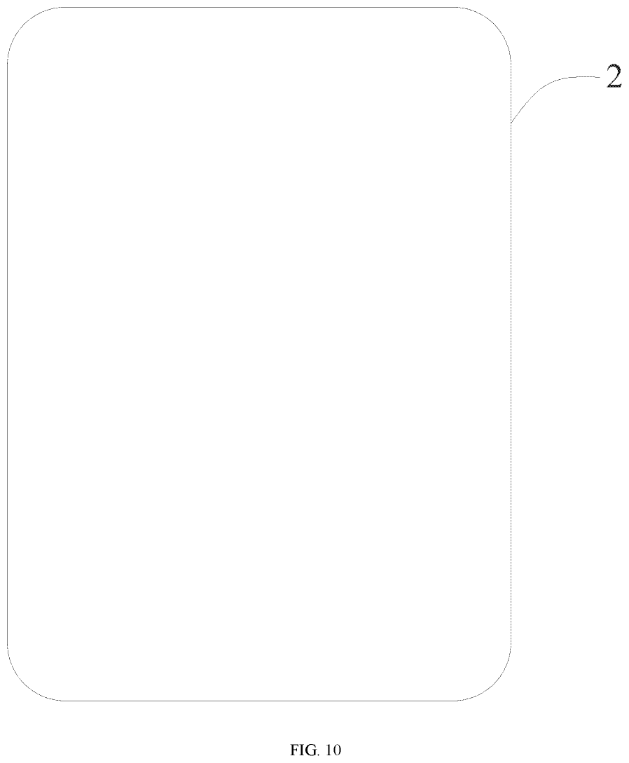

This application also provides an array substrate 2, as shown in FIG. 10, including any one of the thin-film transistors 1 provided in the above embodiments of this application.

In the array substrate 2 provided in this application, the thin-film transistor 1 has improved mobility compared to conventional structures and illumination stability, so the performance of the array substrate 2 is improved. Moreover, the preparation process of the thin-film transistor 1 in the array substrate 2 provided in this application is relatively simple, taking into account the etching difficulty while ensuring its own mobility and illumination stability, which helps reduce preparation costs.

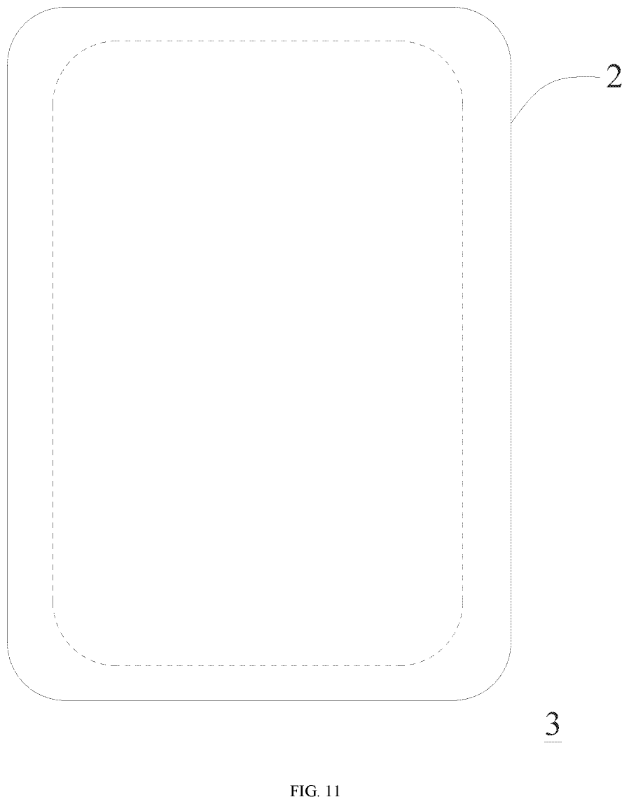

This application also provides a display panel 3, as shown in FIG. 11, including the array substrate 2 provided in the above embodiments of this application.

In the display panel 3 provided in this application, the array substrate 2 has better performance and driving effect, thereby making the performance of the display panel 3 better.

What is claimed is:

1. A thin film transistor, comprising an active layer, wherein the active layer comprises a plurality of sub-active layers, the plurality of sub-active layers are stacked along a first direction, each sub-active layer comprises a crystalline oxide material, and atomic percentage of indium element in adjacent sub-active layers is different.

2. The thin film transistor according to claim 1, wherein the crystalline oxide material comprises indium gallium oxide, and a ratio of total number of atoms in the indium gallium oxide to total number of atoms in the crystalline oxide material is in a range of 70% to 100%.

3. The thin film transistor according to claim 2, wherein the plurality of sub-active layers comprise at least one first sub-active layer and at least one second sub-active layer, atomic percentage of indium element in the first sub-active layer is less than atomic percentage of indium element in the second sub-active layer, and atomic percentage of gallium element in the first sub-active layer is greater than atomic percentage of gallium element in the second sub-active layer.

4. The thin film transistor according to claim 3, wherein the first sub-active layer and the second sub-active layer are alternately arranged along the first direction, the active layer comprises a first side and a second side, the first side and the second side are arranged along the first direction, one of the first sub-active layers is close to the first side, and one of the second sub-active layers is close to the second side.

5. The thin film transistor according to claim 3, wherein in the first sub-active layer, number of atoms of indium element is In1, number of atoms of gallium element is Ga1, X1=In1/(In1+Ga1), Y1=Ga1/(In1+Ga1), wherein 50%≤X1≤80%, 20%≤Y1≤50%.

6. The thin film transistor according to claim 3, wherein in the second sub-active layer, number of atoms of indium element is In2, number of atoms of gallium element is Ga2, X2=In2/(In2+Ga2), Y2=Ga2/(In2+Ga2), wherein 80%≤X2≤100%, 0≤Y2≤20%.

7. The thin film transistor according to claim 3, wherein a dimension of the active layer along the first direction is in a range of 3 nm to 50 nm.

8. The thin film transistor according to claim 7, wherein a dimension of the first sub-active layer along the first direction is in a range of 1 nm to 10 nm.

9. The thin film transistor according to claim 7, wherein a dimension of the second sub-active layer along the first direction is in a range of 0.5 nm to 5 nm.

10. The thin film transistor according to claim 4, wherein in the active layer, atomic percentage of indium element in the first sub-active layer close to the first side or the second sub-active layer close to the second side is greater than or equal to atomic percentage of indium element in any other sub-active layer.

11. The thin film transistor according to claim 1, wherein the active layer further comprises doping particles, and a ratio of total number of atoms of the doping particles to total number of atoms in the crystalline oxide material is greater than 0 and less than or equal to 30%.

12. The thin film transistor according to claim 11, wherein the doping particles comprise at least one of tin and germanium.

13. The thin film transistor according to claim 1, wherein the active layer comprises a first side and a second side, the first side and the second side are arranged along the first direction, and the thin film transistor further comprises:
a source-drain layer, formed on the first side and connected to the active layer; and
a gate electrode, formed on at least one of the first side and the second side, and insulated from the active layer and the source-drain layer.

14. The thin film transistor according to claim 13, wherein the gate electrode is formed on the first side, the gate electrode and the active layer are insulated by a first insulating layer, and the thin film transistor further comprises a second insulating layer, a light-shielding layer, a buffer layer and a substrate which are sequentially stacked on the second side along a direction away from the active layer, and an orthographic projection of the light-shielding layer on the substrate covers an orthographic projection of the gate electrode on the substrate.

15. The thin film transistor according to claim 13, wherein the gate electrode is formed on the second side, and the gate electrode and the active layer are insulated by a first insulating layer.

16. A method for preparing a thin film transistor, comprising:
sequentially depositing crystalline oxide materials having different atomic percentages of indium element to form a plurality of sub-active layers stacked along a first direction, wherein atomic percentage of indium element in adjacent sub-active layers is different, thereby forming an active layer.

17. The preparation method according to claim 16, wherein the active layer comprises a first side and a second side, the first side and the second side are arranged along the first direction, and the preparation method further comprises: forming a gate electrode on the first side or the second side, the gate electrode being insulated from the active layer; and forming a source-drain layer on the first side, the source-drain layer being connected to the active layer and insulated from the gate electrode.

18. The preparation method according to claim 16, wherein the crystalline oxide material is deposited using an atomic layer deposition process.

19. An array substrate, comprising the thin film transistor according to claim 1.

20. A display panel, comprising the array substrate according to claim 19.
